(19) United States
(12) Patent Application Publication
(10) Pub. No.: US 2026/0100235 A1
(43) Pub. Date: Apr. 9, 2026

(54) VOLTAGE VERIFICATION AT A MEMORY SYSTEM

(71) Applicant: Micron Technology, Inc., Boise, ID (US)

(72) Inventors: Mani Balakrishnan, München (DE); Martin Bach, München (DE); Miljana Nenadovic, München (DE); Hemant Madhewar, München (DE); Thomas Hein, München (DE); Martin Brox, München (DE)

(21) Appl. No.: 19/344,031

(22) Filed: Sep. 29, 2025

Related U.S. Application Data
(60) Provisional application No. 63/705,427, filed on Oct. 9, 2024.

(51) Int. Cl. G11C 29/02; G11C 7/12

(52) U.S. Cl. CPC G11C 29/021; G11C 7/12

(57) ABSTRACT

Methods, systems, and devices for reference voltage verification at a memory system are described. The memory system may receive a first signal that indicates to test a voltage source of a set of voltage sources corresponding to a data line of a channel of a memory system and couple the voltage source of the set with an analog-to-digital (ADC) converter to form a conductive path based on receiving the first signal. Further, the memory system may generate, using the ADC, a signal that indicates a value of a reference voltage output from the voltage source based on the conductive path.

### CROSS REFERENCE

The present Application for Patent claims priority to U.S. patent application Ser. No. 63/705,427 by Balakrishnan et al., entitled “VOLTAGE VERIFICATION AT A MEMORY SYSTEM,” filed Oct. 9, 2024, which is assigned to the assignee hereof, and which is expressly incorporated by reference in its entirety herein.

### TECHNICAL FIELD

The following relates to one or more systems for memory, including voltage verification at a memory system.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

### BRIEF DESCRIPTION OF THE DRAWINGS

FIG. 1 shows an example of a system that supports voltage verification at a memory system in accordance with examples as disclosed herein.

FIG. 2 shows an example of a system that supports voltage verification at a memory system in accordance with examples as disclosed herein.

FIG. 3 shows an example of a system that supports voltage verification at a memory system in accordance with examples as disclosed herein.

FIG. 4 shows a block diagram of a memory system that supports voltage verification at a memory system in accordance with examples as disclosed herein.

FIG. 5 shows a flowchart illustrating a method or methods that support voltage verification at a memory system in accordance with examples as disclosed herein.

### DETAILED DESCRIPTION

Testing may be performed on a memory system to verify functionality of one or more voltage sources of the memory system (e.g., reference voltages). In some examples, the memory system may include a set of reference voltage sources for each data line of a channel of the memory system. The reference voltage sources may generate reference voltages that the memory system may use to determine data received via a respective data line, among other uses. Each reference voltage source may include multiple components such as switches and resistors. During manufacturing, defects may occur in one or more components of circuitry associated with a reference voltage source causing an inaccurate reference voltage for the memory system.

To detect such defects, a testing apparatus that is external to the memory system may perform testing on the reference voltage sources. Testing may include the testing apparatus probing each data line of the memory system to validate the voltages generated by each of the reference voltage sources. However, testing with the testing apparatus in such a way may be difficult due to area and circuit constraints of the memory system. Further, testing with the testing apparatus in such a way may be time consuming and in some cases, the testing apparatus may be unable to validate each voltage step of a reference voltage source resulting in inaccurate testing, or in sampling some of the reference voltages with testing and leaving others untested.

As described herein, the memory system may include an internal circuit configured to test each reference voltage source of the memory system. In some examples, the memory system may include a set of reference voltage sources associated with a data line of the memory system, a multiplexing component associated with the data line, and an analog-to-digital converter (ADC) associated with a channel that includes the data line. In some examples, the multiplexing component may receive a signal indicating to a test a reference voltage source of the set. In response to the signal indicating to test the reference voltage source, the multiplexing component may couple the reference voltage source with the ADC to form a conductive path. The reference voltage source may then bias the conductive path to a reference voltage and the ADC may detect the reference voltage.

Upon detecting the reference voltage, the ADC may generate a signal that indicates a value of the reference voltage and output the signal to processing circuitry of the memory system. In some cases, the ADC generates a digital representation of the reference voltage that is capable of being interpreted by the processing circuitry. The processing circuitry may determine the value of the reference voltage based on the signal and verify that the reference voltage source is functioning properly (e.g., by comparing the value of the reference voltage to one or more values stored at the processing circuitry). In some examples, the memory system may perform these steps for each voltage step of the reference voltage source and for each reference voltage source of the memory system. Using the method as described herein may reduce latency and increase accuracy associated with testing reference voltages at a memory system.

In addition to applicability in memory systems as described herein, techniques for reference voltage verification at a memory system may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by ensuring that the electronic devices generate accurate reference voltages, which may decrease errors in access operations and latency associated with these errors, among other benefits.

Features of the disclosure are illustrated and described in the context of systems and architectures. Features of the disclosure are further illustrated and described in the context of block diagrams and flowcharts.

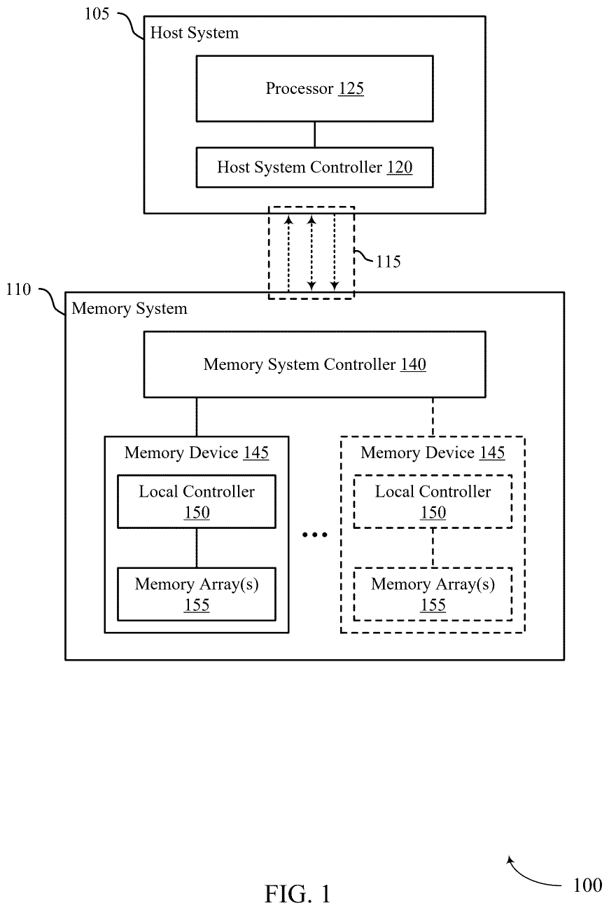

FIG. 1 illustrates an example of a system 100 that supports voltage verification at a memory system in accordance with examples as disclosed herein. The system 100 may include portions of an electronic device, such as a computing device, a mobile computing device, a wireless communications device, a graphics processing device, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

The host system 105 may include one or more components (e.g., circuitry, processing circuitry, one or more processing components) that use memory to execute processes, any one or more of which may be referred to as or be included in a processor 125. The processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. The processor 125 may be an example of a central processing unit (CPU), a graphics processing unit (GPU), a general-purpose GPU (GPGPU), or an SoC or a component thereof, among other examples.

The host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating the memory system 110, such as write commands, read commands, configuration signaling or other operational signaling. In some examples, the host system controller 120, or associated functions described herein, may be implemented by or be part of the processor 125. For example, a host system controller 120 may be hardware, instructions (e.g., software, firmware), or some combination thereof implemented by the processor 125 or other component of the host system 105. In various examples, a host system 105 or a host system controller 120 may be referred to as a host.

The memory system 110 provides physical memory locations (e.g., addresses) that may be used or referenced by the system 100. The memory system 110 may include a memory system controller 140 and one or more memory devices 145 (e.g., memory packages, memory dies, memory chips) operable to store data. The memory system 110 may be configurable for operations with different types of host systems 105, and may respond to commands from the host system 105 (e.g., from a host system controller 120). For example, the memory system 110 (e.g., a memory system controller 140) may receive a write command indicating that the memory system 110 is to store data received from the host system 105, or receive a read command indicating that the memory system 110 is to provide data stored in a memory device 145 to the host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of the memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with the host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 and one or more memory arrays 155. A memory array 155 may be a collection of memory cells (e.g., a two-dimensional array, a three-dimensional array), with each memory cell being operable to store data (e.g., as one or more stored bits). Each memory array 155 may include memory cells of various architectures, such as random access memory (RAM) cells, dynamic RAM (DRAM) cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells, chalcogenide memory cells, not-or (NOR) memory cells, and not-and (NAND) memory cells, or any combination thereof.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

A host system 105 (e.g., a host system controller 120) and a memory system 110 (e.g., a memory system controller 140) may communicate information (e.g., data, commands, control information, configuration information, timing information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 may be dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

A command/address channel (e.g., a CA channel) may be operable to communicate commands between the host system 105 and the memory system 110, including control information associated with the commands (e.g., address information, configuration information). Commands carried by a command/address channel may include a write command with an address for data to be written to the memory system 110 or a read command with an address of data to be read from the memory system 110.

A clock signal channel may be operable to communicate one or more clock signals between the host system 105 and the memory system 110. Clock signals may oscillate between a high state and a low state, and may support coordination (e.g., in time) between operations of the host system 105 and the memory system 110. In some examples, a clock signal may provide a timing reference for operations of the memory system 110. A clock signal may be referred to as a control clock signal, a command clock signal, or a system clock signal. A system clock signal may be generated by a system clock, which may include one or more hardware components (e.g., oscillators, crystals, logic gates, transistors).

A data channel (e.g., a DQ channel) may be operable to communicate (e.g., bidirectionally) information (e.g., data, control information) between the host system 105 and the memory system 110. For example, a data channel may communicate information from the host system 105 to be written to the memory system 110, or information read from the memory system 110 to the host system 105. In some examples, channels 115 may include one or more error detection code (EDC) channels. An EDC channel may be operable to communicate error detection signals, such as checksums or parity bits, which may accompany information conveyed over a data channel.

In some examples, the memory system 110 may include an internal circuit that is configured to test reference voltages for the memory system 110. In some examples, the memory system 110 may receive a signal that indicates to test a voltage source of a set of voltage sources corresponding to a data line of a channel of the memory system 110. Further, using a multiplexer, the memory system 110 may couple the voltage source of the set with an ADC to form a conductive path in response to receiving the signal indicating to test the voltage source. Additionally, the memory system 110 may generate, using the ADC, a signal that indicates a value of the reference voltage output from the voltage source in response to forming the conductive path. Using the methods as described herein may allow the memory system 110 to test reference signal voltages with less latency and more accuracy when compared to other methods.

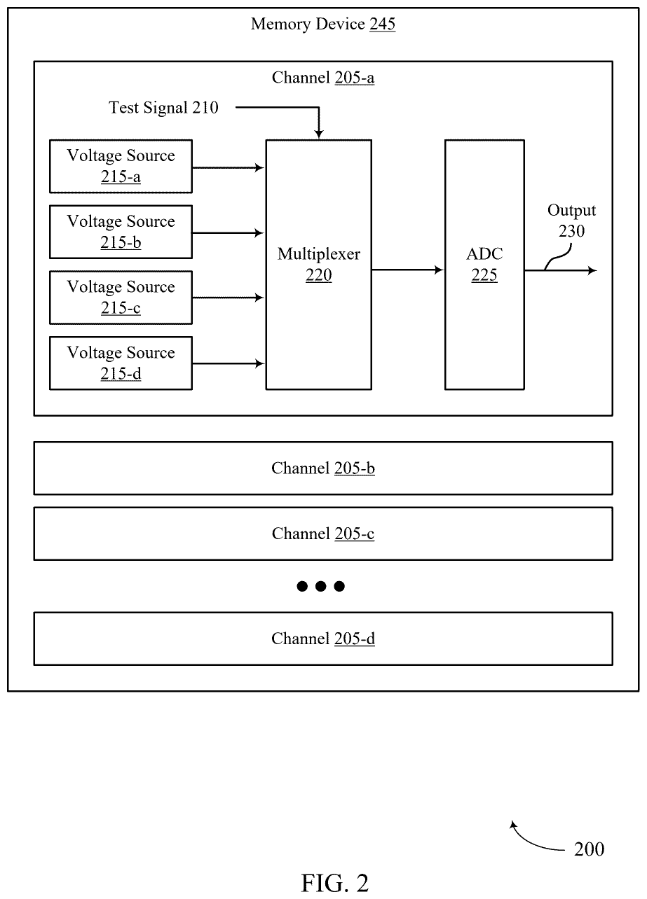

FIG. 2 shows an example of a system 200 that supports voltage verification at a memory system in accordance with examples as disclosed herein. In some examples, the system 200 may implement aspects of a system 100. For example, the system 200 may include a memory device 245 which may be an example of a memory device 145 as described with reference to FIG. 1.

In some examples, a memory device 245 of a memory system may communicate with another device using one or more of a channel 205-a, a channel 205-b, a channel 205-c, and a channel 205-d. To communicate via the channel 205-a, the memory device 245 may include circuitry that is configured to receive and interpret signals communicated to the memory device 245 via the channel 205-a. To interpret the signals, the circuitry may compare a voltage of the signal to one or more reference voltages.

To generate the one or more reference voltages, the memory device 245 may include a voltage source 215-a. In some examples, the voltage source 215-a may generate multiple reference voltages. For example, the voltage source 215-a may generate a first reference voltage (e.g., V_{refdh}) and a second voltage (e.g., V_{refdL}) that is less than the first reference voltage.

Additionally or alternatively, the memory device 245 may include one or more other voltage sources 215 that may generate other voltages for the channel 205-a. For example, the memory device 245 may include a voltage source 215-b that may generate one or more bias voltages (e.g., V_{biash} and V_{biasL}), a voltage source 215-c that may generate one or more decision feedback equalization (DFE) voltages (e.g., V_{dfeh} and V_{dfeL}), a voltage source 215-d that may generate one or more working clock voltages (e.g., V_{wckbias1} and V_{wckbias2}), or a voltage source that may generate one or more CA reference voltages (e.g., V_{refCA}).

Further, each of the voltage sources 215 may be configured with one or more voltage steps. Each voltage step may correspond to an incremental change (e.g., an increase or a decrease) in voltage (e.g., used as part of a testing procedure). For example, the voltage source 215-a, the voltage source 215-b, and the voltage source 215-c may be configured with 128 voltage steps, 64 voltage steps, and 16 voltage steps, respectively (e.g., used as part of a testing procedure). To analyze the reliability and the accuracy of the voltage sources 215 of the channel 205-a, the memory device 245 may cycle through one or more of the voltage steps.

To analyze the reliability and the accuracy of the voltage sources 215 of the channel 205-a, the memory device 245 may include a multiplexer 220 and an ADC 225. As shown in FIG. 2, the multiplexer 220 of the channel 205-a may be coupled with one or more of the voltage source 215-a, the voltage source 215-b, the voltage source 215-c, and the voltage source 215-d, as well as the ADC 225. In some examples, the multiplexer 220 may receive a test signal 210 indicating to test a voltage source 215 of the channel 205-a and in response to receiving the test signal 210, the multiplexer 220 may form a conductive line between the voltage source 215 and the ADC 225. For example, the test signal 210 may indicate to test the voltage source 215-a and in response to the test signal 210 indicating to test the voltage source 215-a, the multiplexer 220 may couple the voltage source 215-a to the ADC 225.

The voltage source 215 may generate a voltage (e.g., V_{refdh}, V_{refdL}, V_{biash}, V_{biasL}, V_{dfeh}, V_{dfeL}, V_{wckbias1}, V_{wckbias2}, or V_{refCA}) and bias the conductive line to the voltage. The ADC 225 may sense the voltage on the conductive line and generate an output signal 230 that indicates the voltage generated by the voltage source 215. In some examples, the output signal 230 may include a series of bits (e.g., 8 bits) that indicates a value of the voltage. As such, the ADC 225 may convert the analog signal of the reference voltage to a digital value (e.g., that is 8 bits). The ADC 225 may output the signal to processing circuitry which may be configured to validate the voltage source 215 in response to receiving the output signal 230. The processing circuitry may validate the voltage source 215 by comparing the value of the voltage indicated in the output signal 230 to a plurality of known voltage values associated with the voltage source 215. If the voltage value is within a threshold range of one of the plurality of known voltage values, the processing circuitry may validate the voltage source 215. In some cases, converting analog information to digital information may enable the memory system to quickly run a test, store results of the test as digital information, and process the results of the test at a later time or using circuitry that does not need to be directly coupled with the channel under test at the time of the test.

In some examples, while the voltage source 215 is coupled with the ADC 225 via the multiplexer 220, the memory device 245 may enter a test mode. While in the test mode, the memory device 245 may instruct the voltage source 215 to generate each of the different voltage steps configured for the voltage source 215. For example, if the voltage source 215-a is under test, the voltage source 215-a may generate the first reference voltage (e.g., V_{refdh}) for each of the voltage steps as well as the second reference voltage (e.g., V_{refdL}) for each of the voltage steps. In turn, the ADC 225 may generate a respective output signal 230 for each of the different voltage steps. After the voltage source 215 generates the voltages in accordance with the test mode, the memory device 245 may exit the test mode and the multiplexer 220 may isolate the voltage source 215 from the ADC 225.

In some examples, the memory device 245 may validate or invalidate each of the voltage sources 215 of the channel 205-a. That is, after validating or invalidating the voltage source 215, the multiplexer 220 may receive one or more second test signals 210 to test other voltage sources 215 of the channel 205-a. For example, the multiplexer 220 may receive a test signal 210 to test the voltage source 215-b, a test signal 210 to test the voltage source 215-c, or a test signal 210 to test the voltage source 215-d. Thus, the memory device 245 may validate or invalidate each of the voltage sources 215 of the channel 205-a.

In some examples, the memory device 245 may include similar circuitry (e.g., circuitry similar to the voltage sources 215, the multiplexer 220, and the ADC 225) for each of the other channels 205 of the memory device 245 (e.g., the channel 205-b, the channel 205-c, and the channel 205-d) such that the memory device 245 apply similar methods to the other channels 205. Using the techniques as described herein, the memory system may test reference voltages sources of one or more channels of the memory device with reduced latency when compared to other methods.

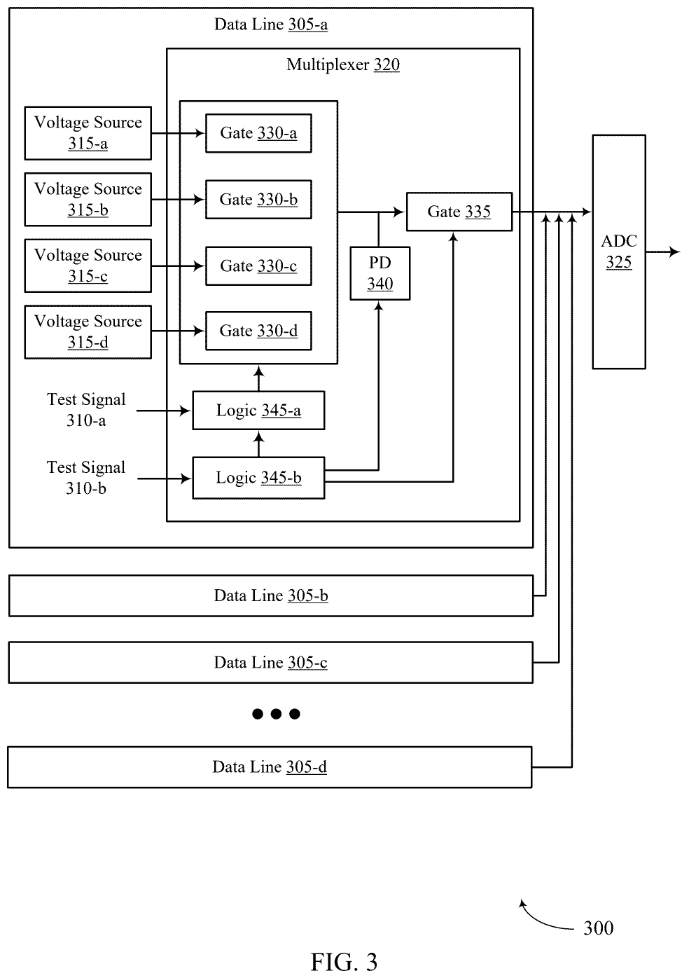

FIG. 3 shows an example of a system 300 that supports voltage verification at a memory system in accordance with examples as disclosed herein. In some examples, the system 300 may implement aspects of a system 100 and a system 200. For example, voltage sources 315 may be examples of the voltage sources 215 as described with reference to FIG. 2. Further, ADC 325 may be an example of the ADC 225 as described with reference to FIG. 2. Moreover, multiplexer 320 may be an example of the multiplexer 220 as described with reference to FIG. 2.

As described with reference to FIG. 2, a memory system may include one or more channels and utilize the one or more channels to communicate signaling to one or more other devices. In some examples, each channel of the one or more channels may include one or more data lines 305 over which the memory system may communicate data (e.g., for storage). For example, each channel may include, at least, a data line 305-a, a data line 305-b, a data line 305-b, and a data line 305-d.

To interpret data sent over a respective data line 305, the memory system may include a set of voltage sources 315 that correspond to the respective data line 305. The set of voltage sources 315 may generate voltages (e.g., reference voltages) for the respective data line 305 that the memory system may utilize to determine the data obtained via the respective data line 305. For example, as shown in FIG. 3, the memory system may include a voltage source 315-a, a voltage source 315-b, a voltage source 315-c, and a voltage source 315-d for the data line 305-a. The voltage source 315-a may generate a first reference voltage (e.g., V_{refdh}). The voltage source 315-b may generate a second reference voltage (e.g., V_{refdL}) that is less than the first reference voltage. The voltage source 315-c may generate a first DFE voltage (e.g., V_{dfeh}). The voltage source 315-d may generate a second DFE voltage (e.g., V_{DFEL}) that is less than the first DFE voltage.

Additionally, the memory system may include a multiplexer for each of the data lines 305 of the channel. For example, as shown in FIG. 3, the memory system may include a multiplexer 320 for the data line 305-a. The multiplexer 320 may include multiple components such as a set of gates 330 (e.g., a gate 330-a, a gate 330-b, a gate 330-c, and a gate 330-d), logic 345-a, logic 345-b, a pull-down circuit 340, and a gate 335. In some examples, each gate 330 of the set of gates 330 may be coupled with a respective voltage source 315 of the data line 305-a. For example, the gate 330-a may be coupled with the voltage source 315-a, the gate 330-b may be coupled with a voltage source 315-b, the gate 330-b may be coupled with the voltage source 315-c, and the gate 330-d may be coupled with the voltage source 315-d. Additionally, each gate 330 of the set of gates 330 may be coupled with the logic 345-a and the gate 335. Additionally, the logic 345-b may be coupled with the logic 345-a, the pull-down circuit 340, and the gate 335.

The memory system may also include an ADC for each channel of the memory system. For example, as shown in FIG. 3, the memory system may include an ADC 325 for the channel that includes the data line 305-a, the data line 305-b, the data line 305-c, and the data line 305-d. The ADC 325 may be coupled with the multiplexer 320 of the data line 305-a and in some examples, may additionally be coupled with other multiplexers of the channel (e.g., a multiplexer of data line 305-b, a multiplexer of data line 305-c, and a multiplexer of data line 305-d). In some examples, outputs of the multiplexers 320 of the different data lines 305 of the channel may be combined and coupled with a single input of the ADC 325.

In some examples, the memory system may perform reference voltage testing and enter a test mode. While in the test mode, the memory system may select a voltage source 315 of a specific data line 305 of the channel to test. As one example, the memory system may select the voltage source 315-b of the data line 305-a to test. In response to selecting the voltage source 315, the memory system may route a test signal 310-a to the logic 345-a and a test signal 310-b to the logic 345-b. The test signal 310-b may indicate that testing is to be performed at the data line 305-a. In some examples, the test signal 310-b may include a first set of bits (e.g., four bits) whose collective logic state indicates the data line 305-a.

In response to receiving the test signal 310-b, the logic 345-b may transmit a deactivation signal to the pull-down circuit 340 such that the pull-down circuit 340 remains in a deactivated state or switches from an activated state to the deactivated state. While in the activated state, the pull-down circuit 340 may be configured to pull-down an input voltage (e.g., a voltage supplied to the pull-down circuit 340 via the gates 330 or the voltage sources 315) to ground. Alternatively, while in the deactivated state, the pull-down circuit 340 may be configured to isolate the input voltage from ground. Additionally or alternatively, the logic 345-b may transmit an activation signal to the gate 335. That is, the logic 345-b may supply a voltage to the gate 335 that causes the gate 335 to form a conductive path between the gates 330 and the ADC 325. Additionally or alternatively, the logic 345-b may transmit an activation signal to the logic 345-a.

The test signal 310-a may indicate that testing is to be performed on the voltage source 315-b. In some examples, the test signal 310-a may include a second set of bits (e.g., 2 bits) whose collective logic value indicates the voltage source 315-b. In response to the test signal 310-a and the activation signal received from the logic 345-b, the logic 345-a may transmit an activation signal to the gate 330-b. That is, the logic 345-a may supply a voltage to the gate 330-b that causes the gate 330-b to form a conductive line between the voltage source 315-b and the gate 335. Thus, in response to the test signal 310-a and the test signal 310-b, the multiplexer 320 may form a conductive line between the voltage source 315-b and the ADC 325.

The voltage source 315-b may bias the conductive line between the voltage source 315-b and the ADC 325 to the second reference voltage. The ADC 325 may sense the second reference voltage and generate an output signal that indicates the second reference voltage generated by the voltage source 315-b. In some examples, the output signal may include a third set of bits (e.g., 8 bits) whose collective logic value indicates the second reference voltage. The ADC may then transmit the output signal to processing circuitry of the memory system. In some examples, the processing circuitry may determine the second reference voltage generated by the voltage source 315-b based on the received output signal and compare the second reference voltage to multiple test voltages (e.g., test voltages stored in memory of the processing circuitry). If the second reference voltage is within a range of a test voltage of the multiple test voltages, the processing circuitry may determine that the voltage source 315-b is functioning properly.

Alternatively, if the processing circuitry determines that the second reference voltage is outside the range, the processing circuitry may determine that the voltage source 315-b (or one or more components of the voltage source 315-b) is not functioning properly. Further, in some examples, the processing circuitry may generate and output an error signal in response to determining that the second reference voltage is outside the range. The processing circuitry may then transmit the error signal to a device external to the memory system (e.g., a host system or a testing apparatus external to the memory system). In some examples, if the memory system outputs one or more error signals during the reference voltage testing, the memory system may be discarded.

In some examples, during the reference voltage testing, the memory system may test and verify functionality of each voltage source 315 of each data line 305 of the channel. Additionally, the memory system may test each voltage step of each of the voltage sources 315. In some examples, the test signal 310-b may indicate to test a data line 305 that is different than the data line 305-a. In such case, the logic 345-b may transmit a deactivation signal to the logic 345-a such that the logic 345-b does not transmit signaling (e.g., an activation signal) to the gates 330 in response to the test signal 310-a. Additionally or alternatively, the logic 345-b may transmit a deactivation signal to the gate 335 such that the gate 335 isolates the gates 330 from the ADC 325. Additionally or alternatively, the logic 345-b may transmit an activation signal to the pull-down circuit such that the pull-down circuit 340 remains in the activated state or switches from the deactivated state to the activated state. In other words, if a voltage source 315 of a data line 305 is not being tested, the voltage sources 315 of the data line 305 are isolated from the ADC 325.

Using the methods as described herein may allow the memory system to perform reference voltage testing with reduced latency when compared to other methods. Further, the methods as described herein may allow the memory system to test all of the voltage steps associated with a voltage source 315 which may provide a more an accurate overview of the functionality of the voltage sources 315 of the memory system when compared to other methods.

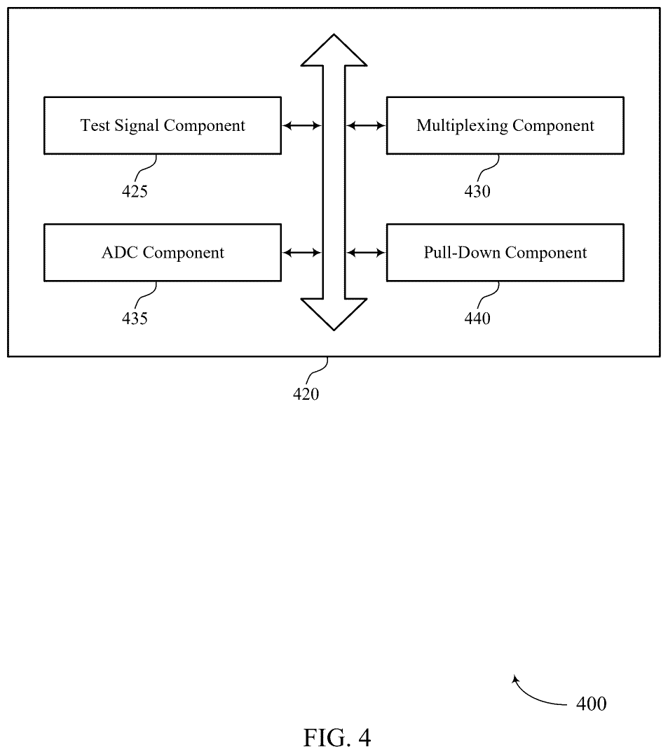

FIG. 4 shows a block diagram 400 of a memory system 420 that supports voltage verification at a memory system in accordance with examples as disclosed herein. The memory system 420 may be an example of aspects of a memory system as described with reference to FIGS. 1 through 3. The memory system 420, or various components thereof, may be an example of means for performing various aspects of voltage verification at a memory system as described herein. For example, the memory system 420 may include a test signal component 425, a multiplexing component 430, an ADC component 435, a pull-down component 440, or any combination thereof. Each of these components, or components of subcomponents thereof (e.g., one or more processors, one or more memories), may communicate, directly or indirectly, with one another (e.g., via one or more buses).

The test signal component 425 may be configured as or otherwise support a means for receiving a first signal that indicates to test a voltage source of a set of voltage sources corresponding to a data line of a channel of a memory system. The multiplexing component 430 may be configured as or otherwise support a means for coupling the voltage source of the set with an ADC to form a conductive path based at least in part on receiving the first signal. The ADC component 435 may be configured as or otherwise support a means for generating, using the ADC, a signal that indicates a value of a reference voltage output from the voltage source based at least in part on the conductive path.

In some examples, the test signal component 425 may be configured as or otherwise support a means for receiving a second signal that indicates to test a second voltage source. In some examples, the multiplexing component 430 may be configured as or otherwise support a means for coupling the second voltage source with the ADC to form a second conductive path based at least in part on receiving the second signal. In some examples, the ADC component 435 may be configured as or otherwise support a means for generating, using the ADC, a signal that indicates a value of the reference voltage output from the voltage source based at least in part on the second conductive path.

In some examples, the second voltage source is included in the set of voltage sources or a second set of voltage sources corresponding to a second data line of the channel. In some examples, the first signal includes a set of bits. In some examples, a logic value of the set of bits corresponds to the voltage source of the set.

In some examples, the test signal component 425 may be configured as or otherwise support a means for receiving a second signal indicating to test the voltage source of the set, where coupling the voltage source with the ADC is based at least in part on receiving the second signal.

In some examples, the pull-down component 440 may be configured as or otherwise support a means for deactivating a pull-down circuit based at least in part on the second signal.

In some examples, the multiplexing component 430 may be configured to couple the voltage source with the ADC by activating a gate of a set of gates, where an input of the gate is coupled with the voltage source of the set and an output of the gate is coupled with the ADC.

In some examples, the described functionality of the memory system 420, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the memory system 420, or various components thereof, may be implemented at least in part by instructions (e.g., stored in memory, non-transitory computer-readable medium) executable by such at least one processor.

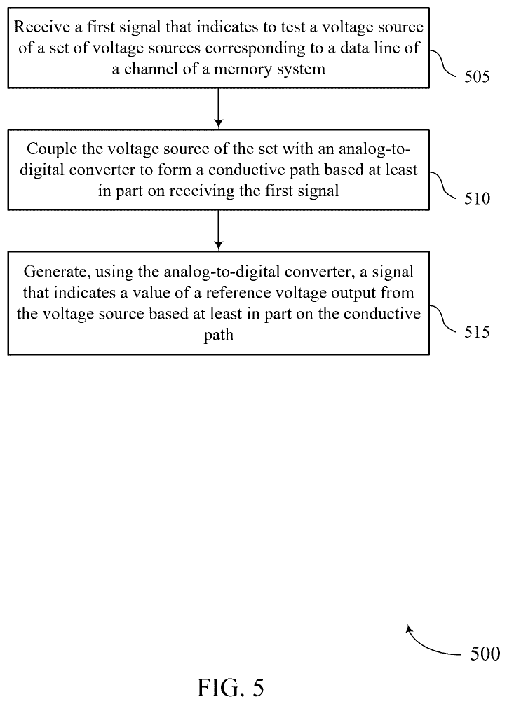

FIG. 5 shows a flowchart illustrating a method 500 that supports voltage verification at a memory system in accordance with examples as disclosed herein. The operations of method 500 may be implemented by a memory system or its components as described herein. For example, the operations of method 500 may be performed by a memory system as described with reference to FIGS. 1 through 4. In some examples, a memory system may execute a set of instructions to control the functional elements of the device to perform the described functions. Additionally, or alternatively, the memory system may perform aspects of the described functions using special-purpose hardware.

At 505, the method may include receiving a first signal that indicates to test a voltage source of a set of voltage sources corresponding to a data line of a channel of a memory system. In some examples, aspects of the operations of 505 may be performed by a test signal component 425 as described with reference to FIG. 4.

At 510, the method may include coupling the voltage source of the set with an ADC to form a conductive path based at least in part on receiving the first signal. In some examples, aspects of the operations of 510 may be performed by a multiplexing component 430 as described with reference to FIG. 4.

At 515, the method may include generating, using the ADC, a signal that indicates a value of a reference voltage output from the voltage source based at least in part on the conductive path. In some examples, aspects of the operations of 515 may be performed by an ADC component 435 as described with reference to FIG. 4.

In some examples, an apparatus as described herein may perform a method or methods, such as the method 500. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for receiving a first signal that indicates to test a voltage source of a set of voltage sources corresponding to a data line of a channel of a memory system; coupling the voltage source of the set with an ADC to form a conductive path based at least in part on receiving the first signal; and generating, using the ADC, a signal that indicates a value of a reference voltage output from the voltage source based at least in part on the conductive path.

Aspect 2: The method, apparatus, or non-transitory computer-readable medium of aspect 1, further including operations, features, circuitry, logic, means, or instructions, or any combination thereof for receiving a second signal that indicates to test a second voltage source; coupling the second voltage source with the ADC to form a second conductive path based at least in part on receiving the second signal; and generating, using the ADC, a signal that indicates a value of the reference voltage output from the voltage source based at least in part on the second conductive path.

Aspect 3: The method, apparatus, or non-transitory computer-readable medium of aspect 2, where the second voltage source is included in the set of voltage sources or a second set of voltage sources corresponding to a second data line of the channel.

Aspect 4: The method, apparatus, or non-transitory computer-readable medium of any of aspects 1 through 3, where the first signal includes a set of bits and a logic value of the set of bits corresponds to the voltage source of the set.

Aspect 5: The method, apparatus, or non-transitory computer-readable medium of any of aspects 1 through 4, further including operations, features, circuitry, logic, means, or instructions, or any combination thereof for receiving a second signal indicating to test the voltage source of the set, where coupling the voltage source with the ADC is based at least in part on receiving the second signal.

Aspect 6: The method, apparatus, or non-transitory computer-readable medium of aspect 5, further including operations, features, circuitry, logic, means, or instructions, or any combination thereof for deactivating a pull-down circuit based at least in part on the second signal.

Aspect 7: The method, apparatus, or non-transitory computer-readable medium of any of aspects 1 through 6, further including operations, features, circuitry, logic, means, or instructions, or any combination thereof for activating a gate of a set of gates, where an input of the gate is coupled with the voltage source of the set and an output of the gate is coupled with the ADC.

It should be noted that the aspects described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 8: A memory system, including: a set of voltage sources associated with a data line of a channel of the memory system, each voltage source of the set configured to generate a respective reference voltage for the data line; a multiplexing component configured to couple a voltage source of the set of voltage sources to an ADC based at least in part on a first signal indicating to test the voltage source of the set; and the ADC configured to output a signal that indicates a value of a voltage output from the voltage source of the set of voltage sources based at least in part on an input from the multiplexing component.

Aspect 9: The memory system of aspect 8, further including: a second set of voltage sources associated with a second data line of the channel, each voltage source of the second set configured to generate a respective reference voltage for the second data line; and a second multiplexing component corresponding to the second data line and configured to couple a voltage source of the second set to the ADC based at least in part on second signal indicating to test the voltage source of the second set, where the ADC is further configured to output a signal that indicates a value of a voltage output from the voltage source of the second set based at least in part on a second input from the multiplexing component.

Aspect 10: The memory system of any of aspects 8 through 9, where the multiplexing component includes: a set of gates, where an input node of each gate of the set is coupled with a respective voltage source of the set and an output of each gate of the set is coupled with the ADC; and a first circuit coupled with a control node of each of the set of gates and configured to activate a gate of the set of gates corresponding to the voltage source of the set based at least in part on the first signal.

Aspect 11: The memory system of aspect 10, where the first signal includes a set of bits that indicate the voltage source of the set.

Aspect 12: The memory system of any of aspects 10 through 11, where the first circuit includes one or more logic gates.

Aspect 13: The memory system of any of aspects 10 through 12, where the multiplexing component further includes: a second circuit coupled with the first circuit and configured to output a third signal to the first circuit that indicates to test the data line, where the first circuit is configured to activate the gate of the set corresponding to the voltage source of the set based on both the first signal and the third signal.

Aspect 14: The memory system of aspect 13, where the second circuit includes one or more logic gates.

Aspect 15: The memory system of any of aspects 13 through 14, where the second circuit is further coupled with a pull-down circuit, and the second circuit is further configured to deactivate the pull-down circuit based at least in part on second signal.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. A conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or may be an indirect conductive path that includes intermediate components, such as switches, transistors, or other components. In some examples, the flow of signals between the connected components may be interrupted for a time, for example, using one or more intermediate components such as switches or transistors.

The term “isolated” may refer to a relationship between components in which signals are not presently capable of flowing between the components. Components are isolated from each other if there is an open circuit between them. For example, two components separated by a switch that is positioned between the components are isolated from each other when the switch is open. When a component isolates two components, the component may initiate a change that prevents signals from flowing between the other components using a conductive path that previously permitted signals to flow.

The term “coupling” (e.g., “electrically coupling”) may refer to condition of moving from an open-circuit relationship between components in which signals are not presently capable of being communicated between the components (e.g., over a conductive path) to a closed-circuit relationship between components in which signals are capable of being communicated between components (e.g., over the conductive path). When a component, such as a controller, couples other components together, the component may initiate a change that allows signals to flow between the other components over a conductive path that previously did not permit signals to flow.

A switching component (e.g., a transistor) discussed herein may be a field-effect transistor (FET), and may include a source (e.g., a source terminal), a drain (e.g., a drain terminal), a channel between the source and drain, and a gate (e.g., a gate terminal). A conductivity of the channel may be controlled (e.g., modulated) by applying a voltage to the gate which, in some examples, may result in the channel becoming conductive. A switching component may be an example of an n-type FET or a p-type FET.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components. ” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory system, comprising:
a set of voltage sources associated with a data line of a channel of the memory system, each voltage source of the set configured to generate a respective reference voltage for the data line;
a multiplexing component configured to couple a voltage source of the set of voltage sources to an analog-to-digital converter based at least in part on a first signal indicating to test the voltage source of the set; and
the analog-to-digital converter configured to output a signal that indicates a value of a voltage output from the voltage source of the set of voltage sources based at least in part on an input from the multiplexing component.

2. The memory system of claim 1, further comprising:
a second set of voltage sources associated with a second data line of the channel, each voltage source of the second set configured to generate a respective reference voltage for the second data line; and
a second multiplexing component corresponding to the second data line and configured to couple a voltage source of the second set to the analog-to-digital converter based at least in part on second signal indicating to test the voltage source of the second set, wherein the analog-to-digital converter is further configured to output a signal that indicates a value of a voltage output from the voltage source of the second set based at least in part on a second input from the multiplexing component.

3. The memory system of claim 1, wherein the multiplexing component comprises:
a set of gates, wherein an input node of each gate of the set is coupled with a respective voltage source of the set and an output of each gate of the set is coupled with the analog-to-digital converter; and
a first circuit coupled with a control node of each of the set of gates and configured to activate a gate of the set of gates corresponding to the voltage source of the set based at least in part on the first signal.

4. The memory system of claim 3, wherein the first signal comprises a set of bits that indicate the voltage source of the set.

5. The memory system of claim 3, wherein the first circuit comprises one or more logic gates.

6. The memory system of claim 3, wherein the multiplexing component further comprises:
a second circuit coupled with the first circuit and configured to output a third signal to the first circuit that indicates to test the data line, wherein the first circuit is configured to activate the gate of the set corresponding to the voltage source of the set based on both the first signal and the third signal.

7. The memory system of claim 6, wherein the second circuit comprises one or more logic gates.

8. The memory system of claim 6, wherein the second circuit is further coupled with a pull-down circuit, and wherein the second circuit is further configured to deactivate the pull-down circuit based at least in part on second signal.

9. A method, comprising:
receiving a first signal that indicates to test a voltage source of a set of voltage sources corresponding to a data line of a channel of a memory system;
coupling the voltage source of the set with an analog-to-digital converter to form a conductive path based at least in part on receiving the first signal; and
generating, using the analog-to-digital converter, a signal that indicates a value of a reference voltage output from the voltage source based at least in part on the conductive path.

10. The method of claim 9, further comprising:
receiving a second signal that indicates to test a second voltage source;
coupling the second voltage source with the analog-to-digital converter to form a second conductive path based at least in part on receiving the second signal; and
generating, using the analog-to-digital converter, a signal that indicates a value of the reference voltage output from the voltage source based at least in part on the second conductive path.

11. The method of claim 10, wherein the second voltage source is included in the set of voltage sources or a second set of voltage sources corresponding to a second data line of the channel.

12. The method of claim 9, wherein the first signal comprises a set of bits, and wherein a logic value of the set of bits corresponds to the voltage source of the set.

13. The method of claim 9, further comprising:
receiving a second signal indicating to test the voltage source of the set, wherein coupling the voltage source with the analog-to-digital converter is based at least in part on receiving the second signal.

14. The method of claim 13, further comprising:
deactivating a pull-down circuit based at least in part on the second signal.

15. The method of claim 9, wherein coupling the voltage source with the analog-to-digital converter comprises:
activating a gate of a set of gates, wherein an input of the gate is coupled with the voltage source of the set and an output of the gate is coupled with the analog-to-digital converter.

16. A memory system, comprising:
one or more memory devices; and
processing circuitry coupled with the one or more memory devices and configured to cause the memory system to:
receive a first signal that indicates to test a voltage source of a set of voltage sources corresponding to a data line of a channel of the memory system;
couple the voltage source of the set with an analog-to-digital converter to form a conductive path based at least in part on receiving the first signal; and
generate, using the analog-to-digital converter, a signal that indicates a value of a reference voltage output from the voltage source based at least in part on the conductive path.

17. The memory system of claim 16, wherein the processing circuitry is further configured to cause the memory system to:
receive a second signal that indicates to test a second voltage source;
couple the second voltage source with the analog-to-digital converter to form a second conductive path based at least in part on receiving the second signal; and
generate, using the analog-to-digital converter, a signal that indicates a value of the reference voltage output from the voltage source based at least in part on the second conductive path.

18. The memory system of claim 17, wherein the second voltage source is included in the set of voltage sources or a second set of voltage sources corresponding to a second data line of the channel.

19. The memory system of claim 16, wherein the first signal comprises a set of bits, and wherein a logic value of the set of bits corresponds to the voltage source of the set.

20. The memory system of claim 16, wherein the processing circuitry is further configured to cause the memory system to:
receive a second signal indicating to test the voltage source of the set, wherein coupling the voltage source with the analog-to-digital converter is based at least in part on receiving the second signal.

21. The memory system of claim 20, wherein the processing circuitry is further configured to cause the memory system to:
deactivate a pull-down circuit based at least in part on the second signal.

22. The memory system of claim 16, wherein, to couple the voltage source with the analog-to-digital converter, the processing circuitry is configured to cause the memory system to:
activate a gate of a set of gates, wherein an input of the gate is coupled with the voltage source of the set and an output of the gate is coupled with the analog-to-digital converter.
